(19) United States
(12) Patent Application Publication
(10) Pub. No.: US 2004/0183179 A1
(43) Pub. Date: Sep. 23, 2004

(54) Package structure for a multi-chip integrated circuit

(76) Inventors: Wen-Lo Shieh, Taipei (TW); Fu-Yu Huang, Taipei (TW); Chia-Chieh Hu, Taipei (TW); Ning Huang, Taipei (TW); Hui-Pin Chen, Taipei (TW); Chang-Ming Hsin, Taipei (TW); Shu-Wan Lu, Taipei (TW); Tou-Sung Wu, Taipei (TW); Chih-Yu Tsai, Taipei (TW); Yu-Tang Su, Taipei (TW); Mei-Hua Chen, Taipei (TW); Chia-Ling Lu, Taipei (TW); Yu-Ju Wang, Taipei (TW)

Correspondence Address: Wen-Lo Shieh, PO Box 82-144, Taipei, TW

(21) Appl. No.: 10/391,783

(22) Filed: Mar. 20, 2003

(51) Int. Cl. H01L 23/02

(52) U.S. Cl. 257/686

(57) ABSTRACT

A package structure for a multi-chip integrated circuit (IC) is disclosed and the structure includes substrate having a position for bonding with chips for chip-bonding and having at least a hole for the passage of a gold wire in the course of wire-bonding, a first chip attached to the substrate with a chip bonding agent and being wire-bonded on the substrate and the chip bonding position being opposite to the 2^{nd} chip with the substrate in-between, and the gold wire of the wire-bonding passed through the hole of the substrate from the substrate bonding pad at the substrate and on the same lateral side of the second chip and being connected to the pin pad of the first chip, at least a second chip being flip-chip bonded onto the substrate and the bonding position being at different sides of the bonding between the substrate and the first chip, and a package body including filler of the second chip extended to cover the hole of the substrate and the first chip and the gold wire connected to the substrate and the pin pad and being bonded with the bonding agent on the chip of the first chip.

### BACKGROUND OF THE INVENTION

(a) Technical Field of the Invention

The present invention relates to a flip chip package, and in particular, a package structure employing the front and rear side of the substrate to form chip configuration so as to improved the I/O numbers of the entire package.

(b) Description of the Prior Art

FIGS. 1A, B, C or FIGS. 2A, B or C show a conventional package. The conventional package is characterized in that the substrates 1a′, 1b′, 1c′ 2a′, 2b′, 2c′ 3a′, 3b′, or 3c′ or two chips (the first chip 11a′, 11b′, 21a′, 21b′, 31a′, 31b′) and the second chip 12a′, 12b′, 22a′, 22b′, 32a′, 32b′) are stacked or the two chips are in parallel or the two chips are bonded to the front and rear side of the substrate 1a′, 1b′, 1c′, 2a′, 2b′, 2c′, 3a′, 3b′, 3c′) and due to the different bonding pad structure (central or peripheral pad) the routes of the gold wires are different.

The above conventional packaging technology cannot be employed on the high I/O density and high functional package for the reason that the wire bonding technique is conventional and the number of the gold wire is limited. The above technology is not suitable to enhance the density of the I/O arrangement.

Accordingly, a main object of the present invention is to provide a packaging structure for a multi-chip integrated circuit which overcomes the above-mentioned drawbacks.

### SUMMARY OF THE INVENTION

The present invention relates to a flip chip package structure employing the front and rear side of the substrate to form chip configuration so as to improve the I/O numbers of the entire package.

Accordingly, it is an object of the present invention to provide a packaging structure for a multi-chip integrated circuit wherein the I/O density and the function of the package are enhanced.

One aspect of the present invention is to provide package structure for a multi-chip integrated circuit (IC) comprising:

a substrate having a position for bonding with chips for chip-bonding and having at least a hole for the passage of a gold wire in the course of wire-bonding;

a first chip attached to the substrate with a chip bonding agent and being wire-bonded on the substrate and the chip bonding position being opposite to the 2^{nd} chip with the substrate in-between, and the gold wire of the wire-bonding passed through the hole of the substrate from the substrate bonding pad at the substrate and on the same lateral side of the second chip and being connected to the pin pad of the first chip;

at least a second chip being flip-chip bonded onto the substrate and the bonding position being at different sides of the bonding between the substrate and the first chip; and

a package body including filler of the second chip extended to cover the hole of the substrate and the first chip and the gold wire connected to the substrate and the pin pad and being bonded with the bonding agent on the chip of the first chip.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIGS. 1A, B and C and FIGS. 2A, B, and C show a conventional package structure for multi-chip integrated circuit.

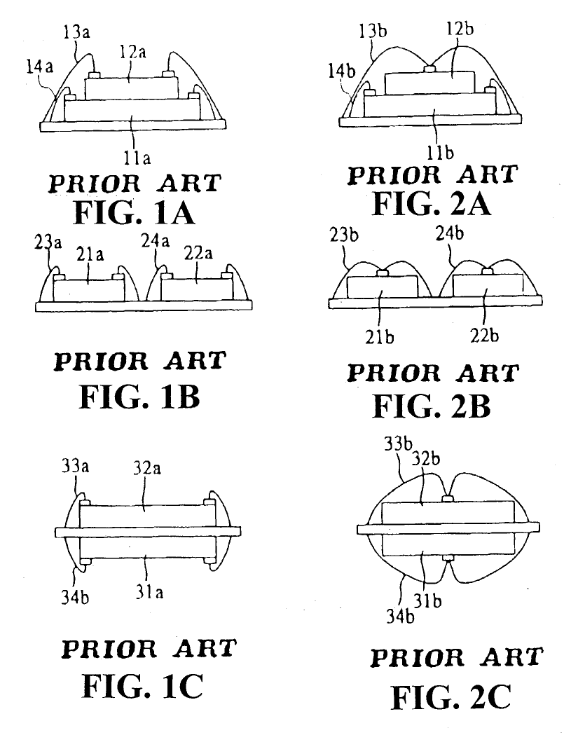

FIGS. 3A, 3B and 3C respectively show the sectional views of the first, second and third preferred embodiments in accordance with the present invention.

### DETAILED DESCRIPTION OF THE PRESENT INVENTION

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

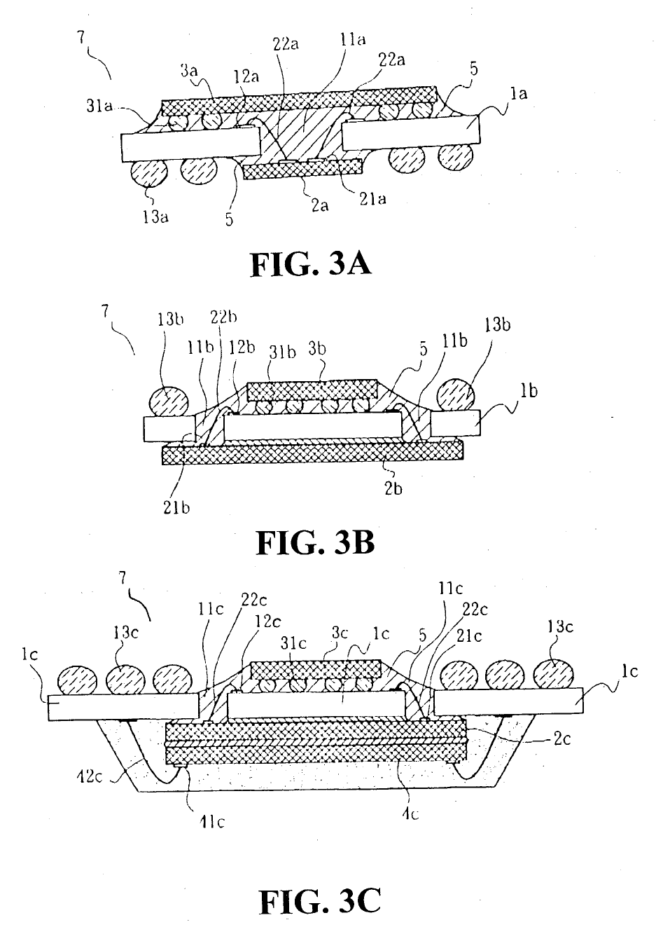

Referring to FIG. 3A, the first preferred embodiment of the present invention and the package A comprises:

a substrate 1a, in which chip 3a will be flip-chip mounted to a pass through-hole in substrate 1a which will allow chip 2a to be wire-bonded on the same side of the substrate before an underfill or molding compound is dispensed to make the structure mechanically rigid.

Referring to FIG. 3B, a second preferred embodiment of the present invention and the package B comprises:

a substrate carrier 1b with a through-hole structure on two peripheries will be used. The side for mounting solder balls will also have a feature for array pads to accommodate the flip chip mounting of chip 3b.

Interconnected bumps 31b will be freely mounted in the center of the substrate away from the area of through-hole and pads for solder balls. Chip 2b will be mounted on the opposite side of substrate 1b in a standard die attach process but will be limited to being epoxy-joined at the center of the chip to free up peripheral bond pads 21b. The bond pads of chip 2b will be connected via wire bonding to aluminum pads located on the opposite side of the substrate.

After this process is completed a compound medium on agent 5 will be used to fill in the area under the flip chip mounted chip 3b as well as the through-hole area 11b in substrate 1b flowing underneath to chip 2b covering the free space on both sides of the substrate 1b, making the solder bump and wire-bond interconnect mechanically rigid. A final process of solder ball mounting 13b will be executed for the package's external connection to a board or another carrier.

From the second preferred embodiment, a third preferred embodiment C is derived. As shown in FIG. 3C, the structure for this figure is similar to 3B except that a two-die stack is employed on the under side of the carrier substrate 1c. A second die on the die of the first die is mounted using conventional methodology.

It is important that the non-active side of the second chip 4C be bonded to the non-active side of chip 2C and eventually expose the bond pads 41C of the second chip. Furthermore, the substrate 1C is a specially designed carrier with bond fingers located on the underside of the purpose of interconnection with second chip 4C.

Because of the active circuit side of second chip 4C and the wire-bonding wires 12C, it is necessary to do over-molding. The encapsulating medium meanwhile will be the protective covering against moisture and mechanical stress for the first chip 2C and second chip 4C and the interconnecting wires 12C.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A package structure for a multi-chip integrated circuit (° C.) comprising:
a substrate having a position for bonding with chips for chip-bonding and having at least a hole for the passage of a gold wire in the course of wire-bonding;
a first chip attached to the substrate with a chip bonding agent and being wire-bonded on the substrate and the chip bonding position being opposite to the 2^{nd} chip with the substrate in-between, and the gold wire of the wire-bonding passed through the hole of the substrate from the substrate bonding pad at the substrate and on the same lateral side of the second chip and being connected to the pin pad of the first chip;
at least a second chip being flip-chip bonded onto the substrate and the bonding position being at different sides of the bonding between the substrate and the first chip; and
a package body including filler of the second chip extended to cover the hole of the substrate and the first chip and the gold wire connected to the substrate and the pin pad and being bonded with the bonding agent on the chip of the first chip.

2. The package structure of claim 1, wherein the position of the hole on the substrate is located at the center position between the second chip and the substrate and the pin pad on the circuit of the wire-bonding between the substrate and the first chip is the center pin pad structure.

3. The package structure of claim 1, wherein the substrate of the located at the bonding of the first chip is provided with ball grid array.

4. The package structure of claim 1, wherein the hole of the substrate is located at the external side position of the bonding region between the substrate the second chip, and the pin pad at the circuit of the wire-bonding of the substrate with the chip is peripheral pin pad.

5. The package structure of claim 1, wherein the substrate located at the same later5al side of the second chip and the external of the hole is provided with ball grid array.

6. The package structure of claim 5, wherein the non circuit of the first chip is chip bonding connected with the non circuit of the third chip and the pin pad of the circuit of the third chip is wire-bonding with the substrate and a chip package agent is used to package the third chip and the first chip.
